(19) United States
(12) Patent Application Publication
(10) Pub. No.: US 2026/0040783 A1
(43) Pub. Date: Feb. 5, 2026

(54) DISPLAY MODULE, MANUFACTURING METHOD, AND DISPLAY DEVICE

(71) Applicants: Guangzhou Govisionox Technology Co., Ltd., Guangzhou (CN); KunShan Go-Visionox Opto-Electronics Co., Ltd., Kunshan (CN)

(72) Inventors: Qingqing Zhang, Guangzhou (CN); Xifeng Zhu, Guangzhou (CN); Hong Zheng, Guangzhou (CN); Chao Chi Peng, Guangzhou (CN)

(73) Assignees: Guangzhou Govisionox Technology Co., Ltd., Guangzhou (CN); KunShan Go-Visionox Opto-Electronics Co., Ltd., Kunshan (CN)

(21) Appl. No.: 19/216,931

(22) Filed: May 23, 2025

Related U.S. Application Data
(63) Continuation of application No. 19/122,321.

(30) Foreign Application Priority Data
Oct. 20, 2022 (CN) 202211291792.3

(51) Int. Cl. H10K 59/131; H10K 59/12; H10K 59/80; H10K 71/70

(52) U.S. Cl. CPC H10K 59/131; H10K 59/1201; H10K 59/8722; H10K 71/70

(57) ABSTRACT

A display module, a manufacturing method, and a display device. The display module includes a display screen, an auxiliary functional layer, an external circuit assembly, and a sealant. A first binding area is arranged on a side where a light exit surface of the display screen is located, and the first binding area is adjacent to a first end of the display screen; the auxiliary functional layer is arranged on a back side of the display screen, and an extended bonding surface is formed on a side of the auxiliary functional layer facing away from the display screen, or is formed by a part of the back side of the display screen that is not covered by the auxiliary functional layer.

### CROSS-REFERENCE TO RELATED APPLICATIONS

The present application is a continuation of U.S. patent application Ser. No. 19/122,321, filed on Apr. 18, 2025, which is a National Stage Entry of International Application No. PCT/CN2023/078895, filed on Feb. 28, 2023, which claims priority to Chinese Patent Application No. 202211291792.3, filed on Oct. 20, 2022, all of which are incorporated herein by reference in their entireties.

### TECHNICAL FIELD

The present application relates to the technical field of display, and in particular to a display module, a manufacturing method, and a display device.

### BACKGROUND

With the rapid development of display technology, flexible display technology has attracted great attention. Flexible display products can form a full-screen display with bendable and foldable performance. Moreover, the requirements of reliability for flexible products are getting higher and higher. In acidic or alkaline environment, an acidic or alkaline high-humidity gas or liquid is likely to intrude into a display panel, corrode a circuit in the display panel, and affect the reliability and stability of a display module.

### SUMMARY

In view of this, the technical problem to be mainly solved by the present application is that the display panel is likely to be corroded and a circuit in the display panel is thus corroded in an acidic or alkaline environment. The present application provides a method for manufacturing a display module and a display device, which enable an improvement in the reliability and stability of the display module.

In order to solve the technical problem described above, a technical solution adopted by the present application is to provide a display module including a display screen, an auxiliary functional layer, an external circuit assembly and a sealant. A first binding area is arranged on a side where a light exit surface of the display screen is located, and the first binding area is adjacent to a first end of the display screen; the auxiliary functional layer is arranged on a back side of the display screen, and an extended bonding surface is formed on a side of the auxiliary functional layer facing away from the display screen, or is formed by a part of the back side of the display screen that is not covered by the auxiliary functional layer; the external circuit assembly is provided with a second binding area, and is bound and connected to the first binding area of the display screen by means of the second binding area, and a part of the external circuit assembly that extends beyond the first end of the display screen forms a first step surface; and the sealant covers at least a part of the first step surface, and integrally covers and is bonded to at least a part of the first end, and the sealant extends to cover and is bonded to the extended bonding surface.

The external circuit assembly includes a flexible printed circuit board. The first binding area of the display screen is provided with a first pin and the second binding area of the flexible printed circuit board is provided with a second pin. The first pin is electrically connected to the second pin.

The present application further includes a second technical solution, i.e., a method for manufacturing a display module, the method including:
providing a display screen, the display screen including a test area and a non-test area, wherein the non-test area is near an end at which a first binding area of the display screen is located;
providing an auxiliary functional layer on the back side of the display screen, wherein an extended bonding surface is formed on a side of the auxiliary functional layer facing away from the display screen, or is formed by a part of the back side of the display screen that is not covered by the auxiliary functional layer, wherein the extended bonding surface is at least partially located in the non-test area and near the end at which the first binding area is located;
cutting away the display screen in the test area, or cutting away the display screen in the test area and the auxiliary functional layer, the first binding area and the extended bonding surface being adjacent to a first end of the display screen in the non-test area;
binding the first binding area of the display screen in the non-test area to a second binding area of an external circuit assembly, a part of the external circuit assembly that extends beyond the first end of the display screen forming a first step surface; and
manufacturing a sealant such that the sealant integrally covers at least a part of the first step surface, and integrally covers and is bonded to at least a part of the first end and the extended bonding surface.

The present application further includes a third technical solution, i.e., a display device including a drive circuit and the display module described above, the drive circuit being configured to drive the display module.

### BRIEF DESCRIPTION OF THE DRAWINGS

FIG. 1a is a schematic partial cross-sectional view of the structure of an embodiment of a display module.

FIG. 1b is a schematic partial cross-sectional view of the structure of an embodiment of the display module of FIG. 1a without a protective film removed.

FIG. 1c is a partial cross-sectional view of an embodiment of the display module of FIG. 1b.

FIG. 2a is a schematic partial cross-sectional view of the structure of a first embodiment of a display module of the present application.

FIG. 2b is a schematic partial cross-sectional view of the structure of a second embodiment of the display module of the present application.

FIG. 3 is a schematic partial cross-sectional view of the structure of a third embodiment of the display module of the present application.

FIG. 4a is a schematic partial cross-sectional view of the structure of a fourth embodiment of the display module of the present application.

FIG. 4b is a schematic partial cross-sectional view of the structure of a fifth embodiment of the display module of the present application.

FIG. 5 is a schematic partial cross-sectional view of the structure of a sixth embodiment of the display module of the present application.

FIG. 6a is a schematic partial cross-sectional view of the structure of a seventh embodiment of the display module of the present application.

FIG. 6b is a schematic partial cross-sectional view of the structure of an eighth embodiment of the display module of the present application.

FIG. 7 is a schematic partial cross-sectional view of the structure of a ninth embodiment of the display module of the present application.

FIG. 8a is a schematic partial cross-sectional view of the structure of a tenth embodiment of the display module of the present application.

FIG. 8b is a schematic partial cross-sectional view of the structure of an eleventh embodiment of the display module of the present application.

FIG. 9 is a schematic partial cross-sectional view of the structure of a twelfth embodiment of the display module of the present application;

FIG. 10 is a schematic partial cross-sectional view of the structure of a thirteenth embodiment of the display module of the present application.

FIG. 11 is a schematic cross-sectional view of the structure of a fourteenth embodiment of the display module of the present application.

FIG. 12 is a schematic plan view of the structure of the display module of the present application.

FIG. 13a is a schematic partial cross-sectional view of the structure of an embodiment of a display module as a first comparative sample.

FIG. 13b is a partial cross-sectional view of an embodiment of the display module of FIG. 13a.

FIG. 14 is a schematic cross-sectional view of the structure of an embodiment of a display module of the present application.

FIG. 15 is a schematic plan view of the structure of an embodiment of the display module of the present application.

FIG. 16 is a flow chart of an embodiment of a method for manufacturing a display module of the present application.

FIG. 17 shows a flow chart of another embodiment of a method for manufacturing a display module of the present application.

FIG. 18a is a schematic partial cross-sectional view of the structure of a first embodiment of a display module having a test area of the present application.

FIG. 18b is a schematic partial cross-sectional view of the structure of FIG. 18a with the test area cut away.

FIG. 19a is a schematic partial cross-sectional view of the structure of a second embodiment of the display module having a test area of the present application.

FIG. 19b is a schematic partial cross-sectional view of the structure of FIG. 19a with the test area cut away.

FIG. 20a is a schematic partial cross-sectional view of the structure of a third embodiment of the display module having a test area of the present application.

FIG. 20b is a schematic partial cross-sectional view of the structure of FIG. 20a with the test area cut away.

FIG. 21a is a schematic partial cross-sectional view of the structure of a fourth embodiment of the display module having a test area of the present application.

FIG. 21b is a schematic partial cross-sectional view of the structure of FIG. 21a with the test area cut away.

FIG. 22a is a schematic partial cross-sectional view of the structure of a fifth embodiment of the display module having a test area of the present application.

FIG. 22b is a schematic partial cross-sectional view of the structure of FIG. 22a with the test area cut away.

FIG. 23a is a schematic partial cross-sectional view of the structure of a sixth embodiment of the display module having a test area of the present application.

FIG. 23b is a schematic partial cross-sectional view of the structure of FIG. 23a with the test area cut away.

### DETAILED DESCRIPTION

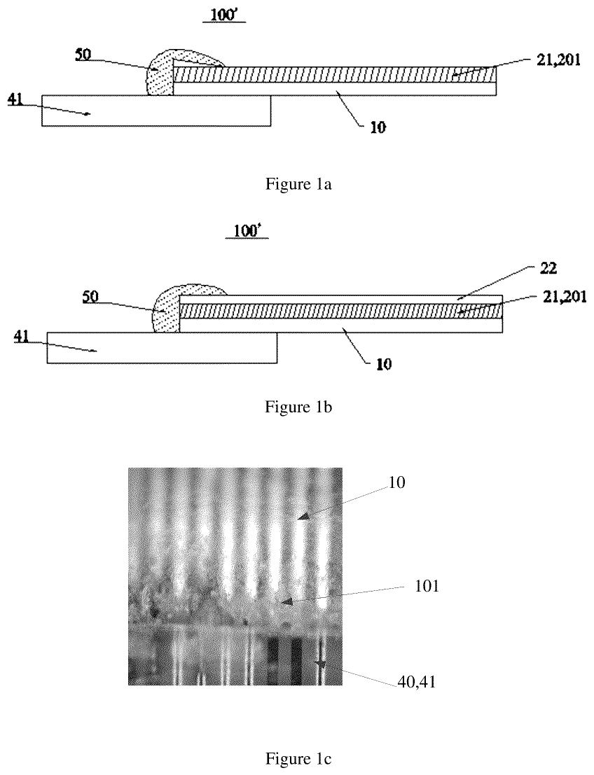

At present, as shown in FIG. 1a, an array substrate of a display screen 10 has circuit traces, and it is necessary to test the display screen 10 before subsequent assembly of the display screen 10, so as to detect whether a circuit in the display screen 10 is abnormal, to avoid subsequent waste of processes. Prior to a test, a support film 201 is attached to the back side of a flexible display screen to serve as an auxiliary functional layer 21, and a protective film 22 is attached to a side of the support film 201 facing away from the display screen to support and protect the flexible display screen. After the test, the display screen 10 in a test area and the corresponding support film 201 and protective film 22 are cut away, to form the post-test display screen 10, and the support film 201 and the protective film 22 which are located on the back side of the display screen 10.

The display screen 10 has a binding area, and the display screen 10 is bound to a flexible circuit board 41. In order to prevent an acidic or alkaline high-humidity gas or liquid from subsequently entering the display screen 10 to corrode the circuit in the display screen 10, a sealant 50 is sprayed to an end of the display screen 10 at a position where the display screen 10 is bound to the flexible circuit board 41. The sealant 50 seals the end of the display screen 10 and overlaps the back side of the protective film 22, as a result of the spraying process.

After the binding of the display screen 10 to the flexible circuit board 41 is completed, it is possible to perform a process of manufacturing a touch circuit, a polarizer, a cover plate, etc. on a light exit surface of the display screen 10. The protective film 22 is removed to form a schematic view of the structure of the display module 100′ as shown in FIG. 1a, and a part of the sealant 50 that is located on the protective film 22 has one end attached in an overlapping manner to the back side of the support film 201, and the protective film 22 has a gap with the back side of the support film 201. Alternatively, the part of the sealant 50 that is located on the protective film 22 is integrally attached in an overlapping manner to the back side of the support film 201, but the protective film 22 is not in close contact with the support film 201. The flexible circuit board 41 is then bent to the back side of the display screen 10. In order to achieve a narrow screen display of the display panel, it is also possible to bend the flexible display screen such that the flexible circuit board 41 is located on the back side of the display screen 10. After the display module is manufactured or during later use of the display module, if the display module is in a specific environment of an acidic or alkaline high-humidity gas or liquid, as shown in FIG. 1c, there is an acidic or alkaline crystal 101 between the display screen 10 and the flexible circuit board 41, and the acidic or alkaline crystal is likely to cause corrosion of the display screen 10 and the flexible circuit board 41. There is still a situation of circuit traces in the display screen 10 being corroded.

The applicant has found through research that when the protective film 22 is torn off, it is likely to displace the sealant 50, thereby generating at least a partial slit between the sealant 50 and the end of the display screen 10. Alternatively, when the protective film 22 is torn off, there is no slit between the sealant 50 and the end of the display screen 10, but during later use of the display module, it is likely to further generate a slit between the sealant 50 and the end of display screen 10.

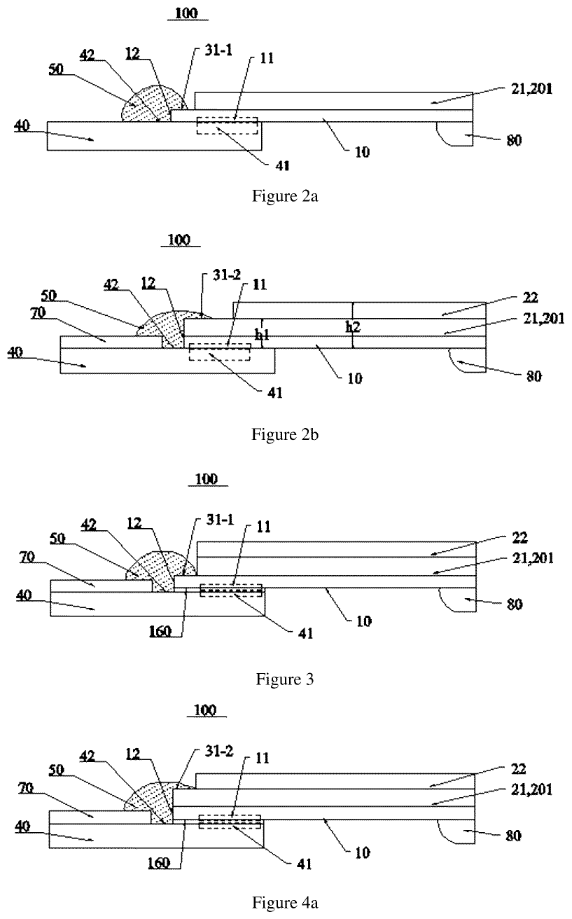

In order to solve the technical problems described above, as shown in FIG. 2a, an embodiment of the present application provides a display module 100, including a display screen 10, an auxiliary functional layer 21, an external circuit assembly 40 and a sealant 50. A first binding area 11 is arranged on a side where a light exit surface of the display screen 10 is located, and the first binding area 11 is adjacent to a first end 12 of the display screen 10. The auxiliary functional layer 21 is provided on a back side of the display screen 10, and an extended bonding surface 31-1 is formed by a part of the back side of the display screen 10 that is not covered by the auxiliary functional layer 21. The external circuit assembly 40 is provided with a second binding area 41. The external circuit assembly 40 is bound and connected to the first binding area 11 of the display screen 10 by means of the second binding area 41, and a part of the external circuit assembly 40 that extends beyond the first end 12 of the display screen 10 forms a first step surface 42. The sealant 50 covers at least a part of the first step surface 42, and integrally covers and is bonded to at least a part of the first end 12, and the sealant 50 extends to cover and is bonded to the extended bonding surface 31-1. In the embodiment of the present application, the extended bonding surface 31-1 is formed by the part, which is covered by the sealant 50, of the back side of the display screen 10 that is not covered by the auxiliary functional layer 21. In another embodiment, as shown in FIG. 2, it is also possible that an extended bonding surface 31-2 is formed by a part, which is covered by the sealant 50, of a side surface of the auxiliary functional layer 21 facing away from the display screen 10. That is, the extended bonding surface may be naturally formed due to the covering of the sealant 50.

As shown in FIGS. 2a and 2b, in the embodiment of the present application, by forming an extended bonding surface 31-2 on the side of the auxiliary functional layer 21 facing away from the display screen 10 or an extended bonding surface 31-2 on the back side of the display screen 10 that is not covered by the auxiliary functional layer 21, and by making the sealant 50 cover at least a partial region of the first step surface 42, the sealant 50 further extends to cover at least a partial region of the first end 12 and the extended bonding surface 31-1 or 31-2, so that the sealant 50 of the display module 100 of the embodiment of the present application can effectively seal an end surface of the first end 12 of the display screen 10, and integrally seal an end of a gap between the external circuit assembly 40 and the display screen 10. The acidic or alkaline high-humidity gas or liquid can be prevented from entering the interior of the display screen 10 from the first end 12 of the display screen 10, corroding a circuit in the display screen 10, and affecting the display of the display screen 10. It is also possible to improve or prevent the ingress of the acidic or alkaline high-humidity gas or liquid between the first binding area 11 and the second binding area 41, i.e. to improve or prevent the ingress of the acidic or alkaline high-humidity gas or liquid into the gap between the external circuit assembly 40 and the display screen 10, thereby avoiding the corrosion of a connection line between the external circuit assembly 40 and the display screen 10 by the acidic or alkaline high-humidity gas or liquid. In an embodiment of the present application, the extended bonding surface 31-1 or 31-2 and the first step surface 42 are formed in the region adjacent to the first end 12 of the display screen 10 such that a step structure is formed in the region adjacent to the first end 12 of the display module 100, and the connection provided between the sealant 50 and the step structure is more secure. In the embodiments of the present application, the sealant 50 may be directly adhered to the extended bonding surface 31-1 or 31-2, or the sealant 50 may be closely adhered to the extended bonding surface 31-1 or 31-2 and the first end 12 of the display screen 10 to prevent the protective film 22 from displacing the sealant 50 when the protective film 22 (see FIG. 1b) is torn off during later use. It is possible to prevent the acidic or alkaline high-humidity gas or liquid from intruding into the interior of the display screen 10 and the space between the display screen 10 and the external circuit from the first end 12 and the surrounding region, thereby improving the stability and reliability of the display module 100 and prolonging the service life of the display module 100.

In the embodiments of the present application, the extended bonding surface 31-1 and the extended bonding surface 31-2 are used to distinguish between the step surfaces of different structures in different embodiments. In the embodiments of the present application, the extended bonding surface 31-1 or 31-2 is a surface configured to be bonded to the sealant 50. Specifically, before the sealant 50 is manufactured, the extended bonding surface 31-1 or 31-2 is an exposed surface, so that the sealant 50 is directly adhered to the extended bonding surface 31-1 or 31-2 when manufactured. The area of the part of the back side of the display screen 10 that is not covered by the auxiliary functional layer 21 is greater than or equal to the area of the extended bonding surface 31-1. As shown in FIG. 2a, the area of the part of the back side of the display screen 10 that is not covered by the auxiliary functional layer 21 is greater than the area of the extended bonding surface 31-1. As shown in FIG. 3, the area of the part of the back side of the display screen 10 that is not covered by the auxiliary functional layer 21 is equal to the area of the extended bonding surface 31-1.

In an embodiment of the present application, the auxiliary functional layer 21 includes a support film 201 for supporting the display screen 10. In another embodiment, the auxiliary functional layer 21 may further include a first adhesive layer configured to bond the support film 201 to the display screen 10. In other embodiments, the auxiliary functional layer 21 may further include another layer structure, for example, may further include an extension layer configured to improve the bending of the display module 100. The specific structure and function of the auxiliary functional layer 21 are not limited in the embodiments of the present application.

In an embodiment of the present application, the display module 100 further includes a covering layer 70. The covering layer 70 is arranged on a surface of the external circuit assembly 40 for protecting the external circuit assembly 40. Specifically, in the embodiment of the present application, the covering layer 70 is arranged on a side of the external circuit assembly 40 facing the auxiliary functional layer 21. In an embodiment of the present application, the covering layer 70 does not completely cover the end of the external circuit assembly 40 adjacent to the first end 12 such that the first step surface 42 is exposed to the covering layer 70. In other words, an end of the first step surface 42 adjacent to the first end is spaced apart from the covering layer. In an embodiment of the present application, the sealant 50 integrally covers and is bonded to a part of the covering layer 70, the first step surface 42, the first end 12 and the extended bonding surface 31-1 or 31-2. In other embodiments, it is also possible that the sealant 50 does not cover and is not bonded to the covering layer 70. The sealant 50 integrally covers and is bonded to the first step surface 42, the first end 12 and the extended bonding surface 31-1 or 31-2. Alternatively, the sealant 50 integrally covers and is bonded to a part of the first step surface 42, a part of the first end 12 and the extended bonding surface 31-1 or 31-2.

In an embodiment of the present application, the display screen 10 includes an array substrate, a light-emitting device arranged on the array substrate, and an encapsulation layer covering the light-emitting device. The array substrate includes a flexible substrate and an array of pixel circuits; The light-emitting device includes an anode layer, an organic light-emitting layer, and a cathode layer. The encapsulation layer includes an inorganic thin film encapsulation layer and an organic thin film encapsulation layer in a laminated arrangement. The specific structure and the material of the light-emitting display layer are not limited in the present application, and can be set according to the display mode of the display module 100. In an embodiment of the present application, the display screen 10 is divided into an active area and a non-active area, and the first binding area 11 is located on the array substrate in the non-active area.

In an embodiment of the present application, the extended bonding surface 31-1 is formed by the part of the back side of the display screen 10 that is not covered by the auxiliary functional layer 21, an distance h1 from the extended bonding surface 31-1 to the light exit surface of the display screen 10 is less than or equal to the maximum distance h2 from the side of the auxiliary functional layer 21 facing away from the display screen 10 to the light exit surface of the display screen 10.

In an embodiment of the present application, the sealant 50 is a waterproof and oxygen-resistant adhesive that can resist water vapor and oxygen to prevent the acidic or alkaline gas or liquid and other water-containing substances and external oxygen from intruding into the display screen 10 and the gap between the display screen 10 and the external circuit assembly 40. In an embodiment of the present application, the sealant 50 is an ultraviolet curing adhesive (UV adhesive). In other embodiments, the sealant 50 may be a Tuffy adhesive, a silicone adhesive, etc.

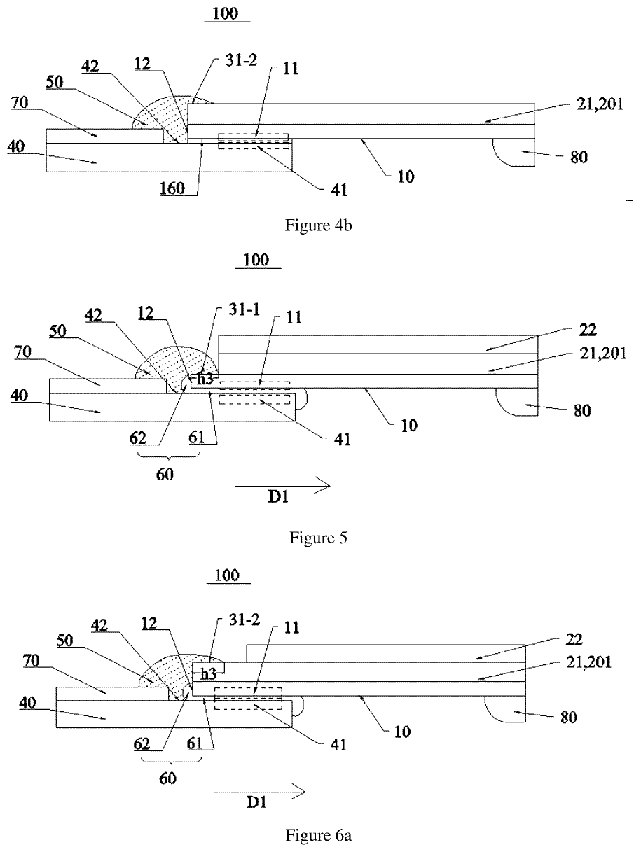

In an embodiment of the present application, as shown in FIGS. 3 and 4a, the display module 100 further includes a conductive adhesive 60. The conductive adhesive 60 is located between the first binding area 11 and the second binding area 41. In the embodiment of the present application, the arrangement of the conductive adhesive 60 between the first binding area 11 and the second binding area 41 can facilitate the electrical connection of the display screen 10 to the external circuit assembly 40. In an embodiment of the present application, the conductive adhesive 60 is an anisotropic conductive film (ACF) adhesive, and the conductive adhesive 60 located between the first binding area 11 and the second binding area 41 may form a conductive adhesive film layer. In an embodiment of the present application, the anisotropic conductive film adhesive is located just between the first binding area 11 and the second binding area 41 by controlling the process. Moreover, the conductive adhesive 60 does not have waterproofness and oxygen resistance. When the sealant 50 of the present application covers the first step surface 42 and integrally covers and is bonded to the first end 12 and the extended bonding surface 31-1 or 31-2, the sealant also covers and is bonded to an end surface of one end of the conductive adhesive film layer, and it is possible to prevent the acidic or alkaline high-humidity gas or liquid from intruding into the space between the display screen 10 and the external circuit along the conductive adhesive film layer and the first end 12, thereby improving or avoiding the corrosion of the connection line between the display screen 10 and the external circuit assembly 40 by the acidic or alkaline high-humidity gas or liquid.

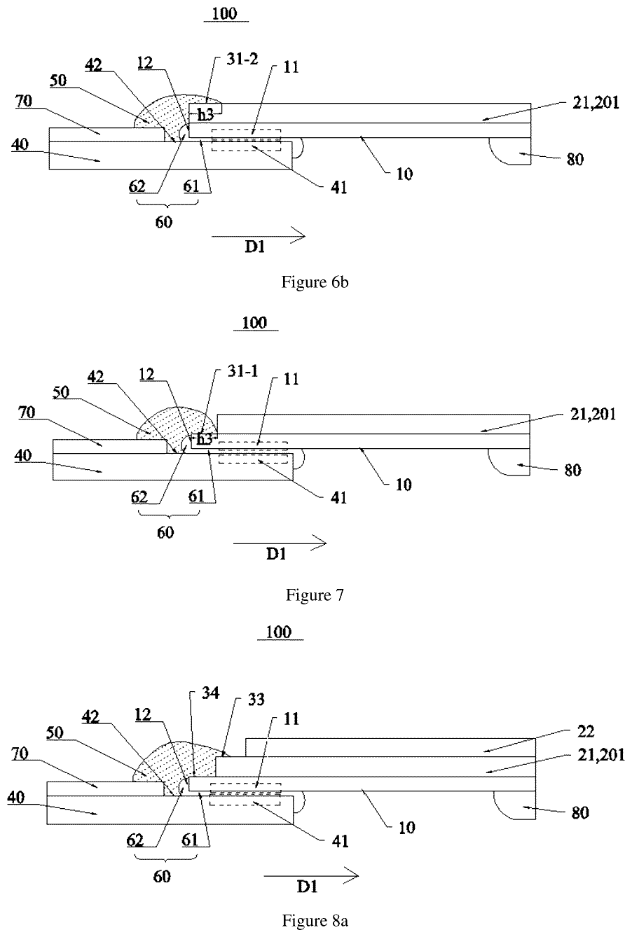

However, as shown in FIGS. 5 and 6a, when the display screen 10 is connected to the external circuit assembly 40, the conductive adhesive 60 located between the first binding area 11 and the second binding area 41 is likely to overflow such that a part of the conductive adhesive 60 is located between the first binding area 11 and the second binding area 41, and the other part of the conductive adhesive is exposed to the first end 12. In other words, the other part of the conductive adhesive is located on outer side of the first end 12. For case of description, the part of the conductive adhesive 60 located between the first binding area 11 and the second binding area 41 is defined as a first sub-conductive adhesive 61; and another part of the conductive adhesive 60 exposed to the first end 12 is defined as a second sub-conductive adhesive 62.

In an embodiment of the present application, the second sub-conductive adhesive 62 is in close contact with the first end 12, or there may be a gap between the second sub-conductive adhesive 62 and the first end 12. In the related solution, during the manufacturing of the sealant 50, the display module 100 has no extended bonding surface 31-1 or 31-2, and during the manufacturing of the conductive adhesive 60, in order to avoid the separation of the sealant 50 from the first end 12 caused by tearing off the protective film 22, the process is controlled to prevent the sealant 50 from adhering to the protective film 22 (see FIG. 1b). However, due to the difference in polarity between the sealant 50 and the conductive adhesive 60, the sealant 50 is in contact with the first step surface 42, but the sealant 50 is not in contact with the end surface of the first end 12. As a result, the sealant 50 may fail to effectively seal the first end 12 of the display screen 10, and the acidic or alkaline high-humidity gas or liquid may intrude into the display screen 10 and the space between the display screen 10 and the external circuit assembly 40 along the slit between the sealant 50 and the first end 12, and corrode the circuit in the display screen 10 and the connection line between the display screen 10 and the external circuit assembly 40, thereby reducing the reliability of the display module 100. In the embodiments of the present application, the extended bonding surface 31-1 or 31-2 is provided, and the sealant 50 covers at least a part of the first step surface 42 and integrally covers and is bonded to the further part of the conductive adhesive 60, at least a part of the first end 12 and the extended bonding surface 31-1 or 31-2, so that the sealant 50 can effectively seal the first end 12 of the display screen 10 and cover the second sub-conductive adhesive 62 to prevent the acidic or alkaline high-humidity gas or liquid from intruding into the display screen 10 along the first end 12, thereby preventing the acidic or alkaline high-humidity gas or liquid from intruding into the connection line between the external circuit assembly 40 and the display screen 10 along the conductive adhesive 60, and improving the stability and reliability of the display module 100.

In an embodiment of the present application, the extended bonding surface 31-1 is formed by the part of the back side of the display screen 10 that is not covered by the auxiliary functional layer 21, and the extended bonding surface 31-1 has a dimension h3 greater than the manufacturing accuracy of the sealant 50 in a direction D1 from the first step surface 42 to the second binding area 41. The sealant 50 covers and is bonded to at least a part of the extended bonding surface 31-1 but does not cover a surface of the auxiliary functional layer 21 facing away from the display screen 10. In an embodiment of the present application, the manufacturing of the sealant 50 is meant that the sealant 50 covers at least a part of the first step surface 42 and integrally covers and is bonded to at least a part of the first end 12 and the extended bonding surface 31-1. The manufacturing accuracy of the sealant 50 is influenced by an instrument for manufacturing the sealant 50, that is, by the accuracy of the instrument for manufacturing the sealant 50. In an embodiment of the present application, the manufacturing accuracy of the sealant 50 is influenced by an adhesive valve, and the manufacturing accuracy of the sealant 50 is the accuracy of the adhesive valve. When other equipment is used to manufacture the sealant 50, the manufacturing accuracy of the sealant may be the accuracy of the other equipment. In an embodiment of the present application, the accuracy of the adhesive valve is less than or equal to 0.1 mm, the dimension of the extended bonding surface 31-1 is greater than 0.1 mm in the direction D1 from the first step surface 42 to the second binding area 41. Specifically, in an embodiment of the present application, the dimension of the extended bonding surface 31-1 is 0.2-0.3 mm. In an embodiment of the present application, the direction from the first step surface 42 to the second binding area 41 is in a direction perpendicular to the end surface of the first end 12. In the embodiment of the present application, by setting the dimension h3 of the extended bonding surface 31-1 to be greater than the manufacturing accuracy of the sealant 50, the sealant 50 does not overflow from the extended bonding surface 31-1 to the back side of the auxiliary functional layer 21 during the manufacturing. That is, the sealant 50 does not cover the surface of the auxiliary functional layer 21 facing away from the display screen 10. The surface of the auxiliary functional layer 21 facing away from the display screen 10 is the entire surface of the auxiliary functional layer 21 that is furthest from the light exit surface of the display screen 10.

As shown in FIGS. 6a and 6b, in another embodiment, an end of the auxiliary functional layer 21 is flush with the first end 12 of the display screen 10, the extended bonding surface 31-2 is formed on the side of the auxiliary functional layer 21 facing away from the display screen 10, the extended bonding surface 31-2 has a dimension greater than the manufacturing accuracy of the sealant in a direction from the first step surface 42 to the second binding area 41, and the sealant 50 covers and is bonded to the extended bonding surface 31-2. In the embodiment of the present application, the extended bonding surface 31-2 is formed on the side of the auxiliary functional layer 21 facing away from the display screen 10, the extended bonding surface 31-2 is exposed during the manufacturing of the sealant 50, so that the sealant 50 can directly cover and be bonded to the extended bonding surface 31-2. In the embodiment of the present application, by setting the dimension h3 of the extended bonding surface 31-1 to be greater than the manufacturing accuracy of the sealant 50, the sealant 50 does not overflow from the extended bonding surface 31-2 to the other regions of the auxiliary functional layer 21 during the manufacturing. The separation of the sealant 50 from the first end 12 caused by tearing off the protective film 22 in the related art can be avoided so that the sealant 50 can integrally cover and be bonded to the extended bonding surface 31-2, the first end 12 and the first step surface 42, and it is possible to prevent the acidic or alkaline high-humidity gas or liquid from intruding into the space between the display screen 10 and the external circuit along the conductive adhesive film layer and the first end 12, thereby improving or avoiding the corrosion of the connection line between the display screen 10 and the external circuit assembly 40 by the acidic or alkaline high-humidity gas or liquid.

In an embodiment of the present application, as shown in FIGS. 3 and 5, the auxiliary functional layer 21 includes a support film 201. The support film 201 is located on the back side of the display screen 10. The display module 100 further includes a protective film 22. The protective film 22 is located on the side of the auxiliary functional layer 21 facing away from the display screen 10. The extended bonding surface 31-1 is formed by a partial region of the back side of the display screen 10 that is not covered by the support film 201, and the extended bonding surface 31-1 is adjacent to the first end 12. The protective film 22 is located on a side of the support film 201 facing away from the display screen 10, and a projection of the protective film 22 on the support film 201 covers the support film 201.

In an embodiment of the present application, the display screen 10 is a flexible display screen, the support film 201 is configured to support the display screen 10, and the protective film 22 is configured to protect the display module 100 and prevent damage to the support film 201. Specifically, in the embodiments of the present application, the protective film 22 is configured to prevent the support film 201 from being damaged by scratches or collisions during transportation; and to prevent foreign matter from adhering to the support film 201. In an embodiment of the present application, one end of the protective film 22 is flush with the support film 201 near the first end 12. In an embodiment of the present application, the extended bonding surface 31-1 is formed by the back side of the display screen 10 that is not covered by the support film 201, such that the sealant 50 covers the first step surface 42, and integrally covers and is bonded to the first end 12 and the extended bonding surface 31-1 during the manufacturing. In other embodiments, it is also possible that the sealant 50 covers a part of the first step surface 42, and integrally covers and is bonded to a part of the first end 12 and the extended bonding surface 31-1. In an embodiment of the present application, the sealant 50 further covers an end surface of one end of the conductive adhesive 60, or the sealant 50 covers the second sub-conductive adhesive 62. In the embodiment of the present application, the sealant 50 acts to seal the first end 12 of the display screen 10 and one end of the gap between the display screen 10 and the external circuit assembly 40. It is possible to prevent the acidic or alkaline high-humidity gas or liquid from intruding into the first end 12 of the display screen 10 and the connection line between the display screen 10 and the external circuit assembly 40. In the embodiment of the present application, the sealant 50 seals the step structure so that the joining between the sealant 50 and the step structure is more tight and secure, improving the sealing performance of sealant 50. The sealant 50 may cover the second sub-conductive adhesive 62 to avoid the creation of a slit between the sealant 50 and the first end 12.

In an embodiment of the present application, the extended bonding surface 31-1 is formed by the back side of the display screen 10 that is not covered by the support film 201, such that the sealant 50 does not cover the protective film 22 when covering the extended bonding surface 31-1. That is, the sealant 50 will not be located on the end surface of the end of the protective film 22 close to the first end 12, nor on the surface of the protective film 22 facing away from the display screen 10. That is, the protective film 22 does not come into contact with the sealant 50. In the display module 100 of an embodiment of the present application, during later assembly or use, in order to reduce the thickness of the display module, or to avoid breakage of the protective film 22, or to prevent foreign matter from adhering to the surface of the protective film 22 facing away from the display screen 10, the protective film 22 may be removed. Since the sealant 50 does not cover the protective film 22, it is possible to prevent the protective film 22 from being linked with the sealant 50 when the protective film 22 is torn off, causing the tearing of the sealant 50 and the creation of a gap between the sealant 50 and the first end 12 of the display screen 10, so that it is possible to prevent the acidic or alkaline high-humidity gas or liquid from entering the first end 12 of the display screen 10 and the space between the display screen 10 and the external circuit assembly 40, thereby avoiding the corrosion of the circuit in the display screen 10 and the connection line between the display screen 10 and the external circuit assembly 40 by the acidic or alkaline high-humidity gas or liquid, and improving the reliability and stability of the display module 100 and prolonging the service life of the display module 100. In an embodiment of the present application, after the protective film 22 is removed, as shown in FIG. 7, the support film 201 is located on the back side of the display screen 10, the extended bonding surface 31-1 is formed by the back side of the display screen 10 that is not covered by the support film 201, and the extended bonding surface 31-1 is adjacent to the first end 12.

In an embodiment of the present application, as shown in FIGS. 4a and 6a, the auxiliary functional layer 21 includes a support film 201, and the display module 100 further includes a protective film 22. The support film 201 is located on the back side of the display screen 10. The protective film 22 is located on a side of the support film 201 facing away from the display screen 10. An extended bonding surface 31-2 is formed by a partial region, which is not covered by the protective film 22, of the support film 201 on a side facing away from the display screen 10. That is, a projection of the protective film 22 on the auxiliary functional layer 21 does not overlap the extended bonding surface 31-2, in other words, the projection of the protective film 22 on the auxiliary functional layer 21 is located on a outer side of the extended bonding surface 31-2; and the extended bonding surface 31-2 is adjacent to the first end 12. In an embodiment of the present application, the support film 201 forms the extended bonding surface 31-2, and the support film 201 and the protective film 22 form a step structure, so that the sealant 50 seals the first end 12 and an end between the display screen 10 and the external circuit assembly 40, to prevent the acidic or alkaline high-humidity gas or liquid from intruding into the display screen 10 and the space between the display screen 10 and the external circuit assembly 40 from the first end 12, thereby avoiding the corrosion of the circuit in the display screen 10 and the connection line between the display screen 10 and the external circuit assembly 40 by the acidic or alkaline high-humidity gas or liquid. In an embodiment of the disclosure, the extended bonding surface 31-2 is formed such that when the sealant 50 covers the extended bonding surface 31-2, the sealant 50 can cover the support film 201 but does not cover the protective film 22, and the sealant 50 is not in contact with the protective film 22, so that the display module 100 does not damage the sealant 50 during the later tearing of the protective film 22, without causing the separation of the sealant 50 from the first end 12 to occur, thereby improving the stability and reliability of the display module 100.

It should be noted that in an embodiment of the present application, the area of the extended bonding surface 31-2 is less than or equal to that of a region, which is not covered by the protective film 22, of the support film 201 on the side facing away from the display screen 10.

In an embodiment of the present application, in order to reduce the thickness of the display module, or to avoid breakage of the protective film 22, or to prevent foreign matter from adhering to the surface of the protective film 22 facing away from the display screen 10, the protective film 22 is removed. In an embodiment of the present application, the display module 100 protects the display screen 10, the support film 201, the external circuit assembly 40 and the sealant 50. As shown in FIGS. 4b and 6b, the support film 201 is located on the back side of the display screen 10; and the extended bonding surface 31-2 of the support film 201 is adjacent to the first end 12, the sealant 50 covers at least a part of the first step surface 42, and integrally covers and is bonded to at least a part of the first end 12, and the sealant 50 extends to cover and is bonded to the extended bonding surface 31-2. The sealant 50 may further cover and be bonded to the end surface of the conductive adhesive 60 or the second sub-conductive adhesive 62.

In an embodiment of the present application, the projection of the support film 201 on the display screen 10 covers an edge of the display screen 10 adjacent to the first end 12. In an embodiment of the present application, the support film 201 is flush with the first end 12 of the display screen 10. The sealant 50 may cover the first step surface 42, and integrally cover and be bonded to the first end 12, the end surface of one end of the support film 201 and the extended bonding surface 31-2 during the manufacturing. In other embodiments, the sealant 50 may cover a part of the first step surface 42, and integrally cover and be bonded to a part of the first end 12, a part of the end surface of one end of the support film 201 and the extended bonding surface 31-2 during the manufacturing.

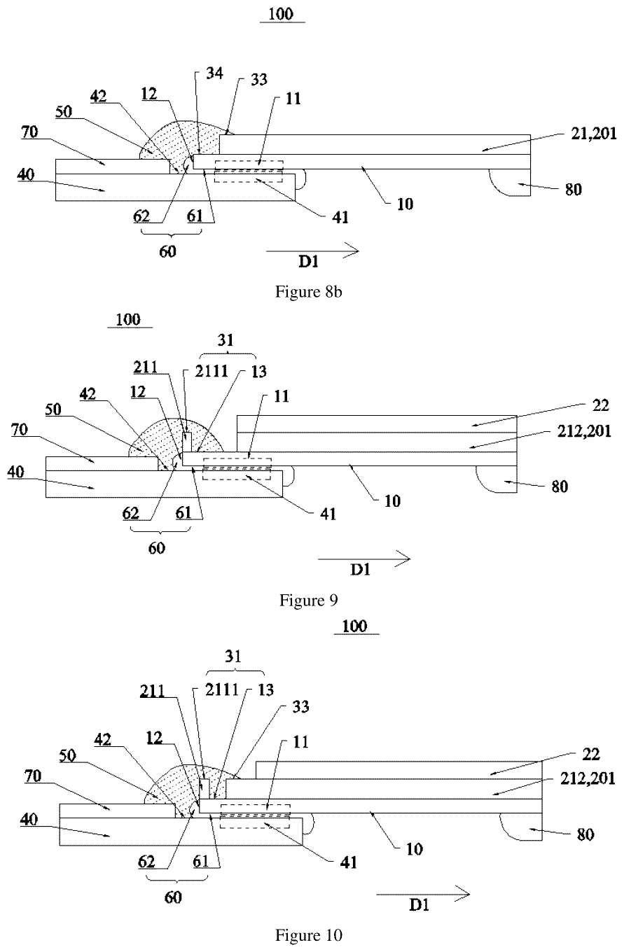

In another embodiment of the present application, as shown in FIGS. 8a and 8b, the auxiliary functional layer 21 includes a support film 201, a first extended bonding surface 33 is formed on a side of the support film 201 facing away from the display screen 10, and a second extended bonding surface 34 is formed by a part of the back side of the display screen 10 that is not covered by the support film 201. The sealant 50 covers the first step surface 42, and integrally covers and is bonded to the first end 12; and the sealant 50 extends to cover and is bonded to the first extended bonding surface 33 and the second extended bonding surface 34. In other words, the auxiliary functional layer and the display screen include the extended bonding surface respectively, the extended bonding surface of the auxiliary functional layer includes a first extended bonding surface, and the extended bonding surface of the display screen includes a second extended bonding surface. In other embodiments, the sealant 50 covers a part of the first step surface 42, and integrally covers and is bonded to a part or the entirety of the first end 12; and the sealant 50 extends to cover and is bonded to the second extended bonding surface 34 and the first extended bonding surface 33.

Specifically, in an embodiment of the present application, as shown in FIG. 8a, the display module 100 further includes a protective film 22. The protective film 22 is located on the side of the auxiliary functional layer 21 facing away from the display screen 10. The first extended bonding surface 33 is formed by a partial region, which is not covered by the protective film 22, of the support film 201 on a side facing away from the display screen 10. That is, a projection of the protective film 22 on the auxiliary functional layer 21 does not overlap the first extended bonding surface 33. The projection of the support film 201 on the display screen 10 does not cover a partial region of the display screen 10 adjacent to the first end 12, and the second extended bonding surface 34 is formed on the back side of the partial region of the display screen 10 adjacent to the first end 12. In an embodiment of the present application, the first step surface 42, the second extended bonding surface 34 and the first extended bonding surface 33 together form a step structure in the vicinity of the first end 12, such that the sealant 50 can come into contact with the first step surface 42, the second extended bonding surface 34 and the first extended bonding surface 33 during the manufacturing. By providing the two extended bonding surfaces, the joining strength of the sealant 50 with the external circuit assembly 40, the display screen 10 and the auxiliary functional layer 21 is increased, reducing the probability of cracking of the sealant 50 and the display screen 10, and improving the scaling stability of the sealant 50. Moreover, by providing the two extended bonding surfaces, the creation of a gap between the sealant 50 and the first end 12 caused by the overflow of the conductive adhesive 60 can also be improved. It is possible to prevent the acidic or alkaline high-humidity gas or liquid from intruding into the circuit of the display screen 10 from the first end 12 of the display screen 10, thereby preventing the acidic or alkaline high-humidity gas or liquid to intrude into the connection line between the display screen 10 and the external circuit assembly 40. In an embodiment of the present application, the sealant 50 covers at least a part of the first step surface 42, and integrally covers and is bonded to at least a part of the first end 12, the second extended bonding surface 34, at least a part of the end surface of one end of the support film 201 and the first extended bonding surface 33. In an embodiment of the present application, the sealant 50 further covers and is bonded to the second sub-conductive adhesive 62. In other embodiments, the sealant 50 may further cover and be bonded to the end surface of the conductive adhesive 60.

In an embodiment of the present application, the sum of the dimension of the first extended bonding surface 33 and the dimension of the second extended bonding surface 34 is greater than the manufacturing accuracy of the sealant 50 in the direction D1 from the first step surface 42 to the second binding area 41. In this way, the display sealant 50 is not formed on the protective film 22 during the manufacturing, so that the display module 100 is not linked with the sealant 50 during the later removal of the protective film 22. As shown in FIG. 8b, after removal of the protective film 22, the sealant 50 still covers at least a part of the first step surface 42, and integrally covers and is bonded to at least a part of the first end 12, the second extended bonding surface 34, at least a part of the end surface of one end of the support film 201 and the first extended bonding surface 33. That is, the removal of the sealant 50 does not cause a gap between the sealant 50 and the first end 12, so that the acidic or alkaline high-humidity gas or liquid does not intrude into the display screen 10 and the connection line between the display screen 10 and the external circuit assembly 40 from the first end 12.

In still another embodiment of the present application, as shown in FIG. 9, the auxiliary functional layer 21 includes a support film 201. The support film 201 is located on the back side of the display screen 10. The support film 201 includes a first support portion 211 and a second support portion 212. The first support portion 211 is adjacent to the first end 12. The second support portion 212 has a spacing from the first support portion 211, and the second support portion 212 is located on a side of the first support portion 211 away from the first end 12. The extended bonding surface 31 includes a surface 2111 of the first support portion 211 facing away from the display screen 10 and a partial region of the back 13 of the display screen 10 at the spacing. In other embodiments, it is also possible that the extended bonding surface 31 includes the surface 2111 of the first support portion 211 facing away from the display screen 10 and the entire region of the back 13 of the display screen 10 at the spacing. In an embodiment of the present application, the support film 201 is provided with a first support portion 211 and a second support portion 212 having a spacing therebetween, such that the sealant 50 can cover and be bonded to the surface 2111 of the first support portion 211 facing away from the display screen 10 (the back side of the first support portion 211) and a partial region of the display screen 10 at the spacing. The sealant 50 may cover at least a part of the first step surface 42, and integrally covers and is bonded to at least a part of the first end 12 of the display screen 10, at least a part of each of two end surfaces of the first support portion 211, at least a part of the back side of the first support portion 211, and at least a part of the back 13 of the display screen 10 at the spacing. The two end surfaces of the first support portion 211 are respectively adjacent to the back side of the first support portion 211. In the display module of the present application, by providing the support film 201 with the first support portion 211 and the second support portion 212, the contact area between the sealant 50 and each of the external circuit assembly 40, the display screen 10 and the auxiliary functional layer 21 can be further increased, thereby enhancing the joining strength of the sealant 50 with the external circuit assembly 40, the display screen 10 and the auxiliary functional layer 21.

In an embodiment of the present application, the display module 100 may further include a protective film 22. The protective film 22 is located on a side of the second support portion 212 facing away from the display screen 10, and the protective film 22 is not provided on the back side of the first support portion 211. In an embodiment of the present application, the protective film 22 covers the second support portion 212. In an embodiment of the present application, the extended bonding surface 31 has a dimension greater than the manufacturing accuracy of the sealant 50 in the direction from the first step surface 42 to the second binding area 41, such that the sealant 50 is not formed on the protective film 22. The protective film 22 is not connected to the sealant 50, so that the protective film 22 is not linked with the sealant 50 when removed, and does not affect the sealing stability of the sealant 50. In other embodiments, as shown in FIG. 10, it is also possible that the protective film 22 forms a step structure with the second support portion 212, a third extended bonding surface 33 is formed by a partial region, which is not covered by the protective film 22, of the second support portion 212 on the side facing away from the display screen 10, and the sum of the dimension of the extended bonding surface 31 and the dimension of the third extended bonding surface 33 is greater than the manufacturing accuracy of the sealant 50 in the direction D1 from the first step surface 42 to the second binding area 41. The sealant 50 may cover at least a part of the first step surface 42, and integrally cover and be bonded to at least a part of the first end 12 of the display screen 10, at least a part of each of two end surfaces of the first support portion 211, at least a part of the back side of the first support portion 211, at least a part of the back side 13 of the display screen 10 at the spacing, and the third extended bonding surface 33. It is possible to improve the joining strength of the sealant 50 with the display screen 10, to prevent the acidic or alkaline high-humidity gas or liquid from intruding into the circuit in the display screen 10 from the first end 12, and to prevent the acidic or alkaline high-humidity gas or liquid from intruding into the connection line between the display screen 10 and the external circuit from the vicinity of the first end 12.

As shown in FIG. 10, it is also possible that the protective film 22 is removed from the display module 100, and the third extended bonding surface 33 is formed by a partial region of the second support portion 212 on the side facing away from the display screen 10. The sealant 50 may cover at least a part of the first step surface 42, and integrally cover and be bonded to at least a part of the first end 12 of the display screen 10, at least a part of each of two end surfaces of the first support portion 211, at least a part of the back side of the first support portion 211, at least a part of the back side 13 of the display screen 10 at the spacing, and the third extended bonding surface 33.

In an embodiment of the present application, the external circuit assembly 40 includes a flexible printed circuit board. The first binding area 11 of the display screen 10 is provided with a first pin and the second binding area 41 of the flexible printed circuit board is provided with a second pin. The first pin is electrically connected to the second pin. In an embodiment of the present application, the sealant 50 may prevent the acidic or alkaline high-humidity gas or liquid from intruding into the first pin and the second pin between the flexible printed circuit board and the display screen 10, thereby avoiding the corrosion of the first pin and the second pin.

In other embodiments, it is also possible that the external circuit assembly 40 includes a flexible printed circuit board and a chip on film. A second binding area 41 of the chip on film is bound to the first binding area 11 of the display screen 10, and the flexible printed circuit board is bound to the chip on film.

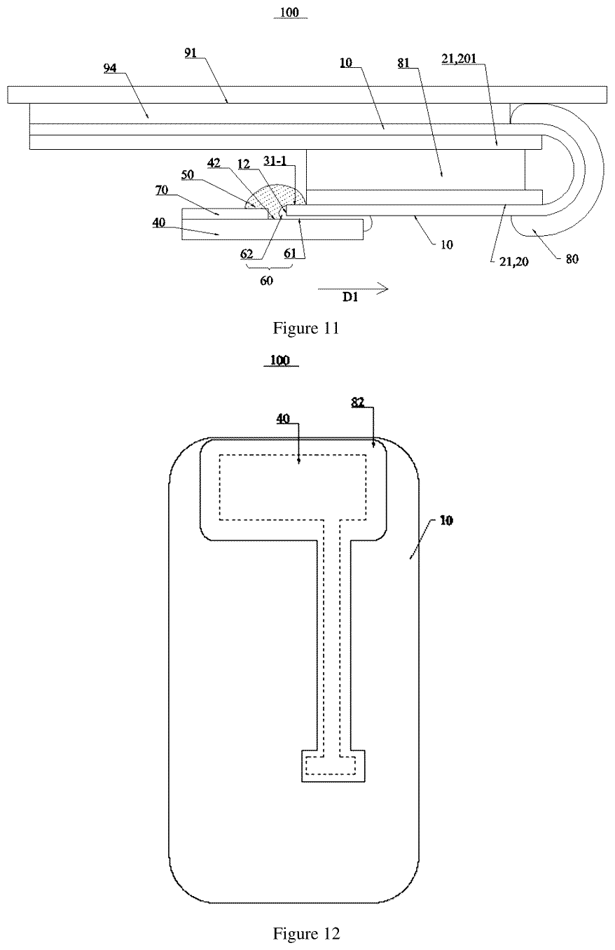

As shown in FIG. 11, in the display module 100 of an embodiment of the present application, the external circuit assembly 40 is bent to the back side of the display screen 10 to facilitate the narrow screen display of the display module 100. Specifically, in the embodiment of the present application, the display screen 10 is bent such that the external circuit assembly 40 is located on the back side of the display screen 10, and a protection layer 80 is provided in the bent region of the display screen 10 to reduce the stress caused by the bending of the display screen 10. Moreover, a spacer 81 is located on the back side of the display screen 10.

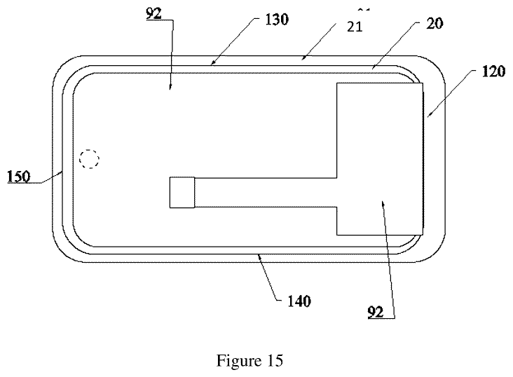

In an embodiment of the present application, as shown in FIGS. 11, 14 and 15, the display module further includes a cover plate 91, a protective layer 92 and a reinforcing adhesive 93. The cover plate 91 is provided at the light exit surface of the display screen 10, a second step surface 911 is formed by a part of a surface of the cover plate 91 that is not covered by the display screen 10 and faces the display screen 10, and the second step surface 911 is adjacent to the side on which the first binding area 11 (see FIG. 1) is located. The cover plate 91 includes at least one second step surface 911. The protective layer 92 is arranged on a surface of the auxiliary functional layer 21 facing away from the display screen 10, a third step surface 23 is formed by a surface of the auxiliary functional layer 21 that is not covered by the protective layer 92 and faces the protective layer 92, and the third step surface 23 is located on the same side as the second step surface 911. The auxiliary functional layer includes at least one third step surface. The reinforcing adhesive 93 integrally covers at least a part of the second step surface 911, at least a part of a side surface of each of the display screen 10 and the auxiliary functional layer 21, and at least a part of the third step surface 23.

In the display module of the embodiment of the present application, the provision of the protective layer 92 can further protect the display screen 10. The projection of the protective layer 92 on the auxiliary functional layer 21 does not completely cover the auxiliary functional layer 21 such that the third step surface 23 is formed on the side of the auxiliary functional layer 21, and the formation of a step structure between the auxiliary functional layer 21 and the protective layer 92 allows the reinforcing adhesive 93 to integrally cover at least a part of the second step surface 911, at least a part of the side surface of the display screen 10, at least a part of the side surface of the auxiliary functional layer 21 and at least a part of the third step surface 23. The embodiment of the present application can reduce the occurrence of overflow or incomplete coating of the reinforcing adhesive 93 due to the instability of an adhesive valve and the fluidity of the reinforcing adhesive 93 during manufacturing of the reinforcing adhesive 93. In the embodiment of the present application, by providing a step structure such as the second step surface 911 and the third step surface 23, the reinforcing adhesive 93 does not overflow from the cover plate 91 and is completely coated during the manufacturing, so that the occurrence of water vapor intrusion caused by incomplete coating of the reinforcing adhesive 93 can be avoided and the stability of the display module 100 can be improved.

The reinforcing adhesive 93 in the embodiment of the present application has a water-blocking effect. In other embodiments, it is also possible that the reinforcing adhesive 93 has a water-blocking and oxygen-blocking effect.

In an embodiment of the present application, the material of the protective layer 92 includes copper foil and foam. The foam is located between the copper foil and the auxiliary functional layer 21. The protective layer 92 has the function of protecting the display screen 10, and the protective layer 92 also has the function of shielding signals, thereby reducing the interference of unnecessary signals on the display module 100. In other embodiments, the protective layer 92 may be of other materials. In an embodiment of the present application, there may also be a touch circuit layer, a polarizer and a planarization layer 94 between the display screen 10 and the cover plate 91. An edge of each of the touch circuit layer, the polarizer and the planarization layer 94 may be flush with an edge of the display module 100.

In an embodiment of the present application, the display module 100 has four sides, among which a first side 120 is the side where the bent region, which is formed by the external circuit assembly 40 bent to the back side of the display screen 10, is located; a second side 130 and a third side 140 are sides both adjacent to the first side 120; and a fourth side 150 is opposite to the first side 120.

In an embodiment of the present application, the third step surface 23 is provided on each of the second side 130 and the third side 140 of the display module 100. In the embodiment of the present application, by further providing the third step surface 23 on each of the second side 130 and the third side 140, the reinforcing adhesive 93 of the display module 100 on the second side 130 and the third side 140 has better protective properties, and a better water-blocking effect can be achieved, thereby improving the performance of the display module 100 in preventing water vapor intrusion.

In other embodiments, it is also possible that the third step surface 23 is provided on the second side 130 or the third side 140 of the display module 100, or that the third step surface 23 is provided on each of the second side 130, the third side 140 and the fourth side 150 of the display module 100, to improve the performance of the display module 100 in preventing water vapor intrusion.

As shown in FIG. 12, in the display module 100 of an embodiment of the present application, the external circuit assembly 40 is bent to the back side of the display screen 10 and the external circuit assembly 40 is covered by an insulating tape 82, such that a peripheral side of the insulating tape is attached to the back side of the display screen 10.

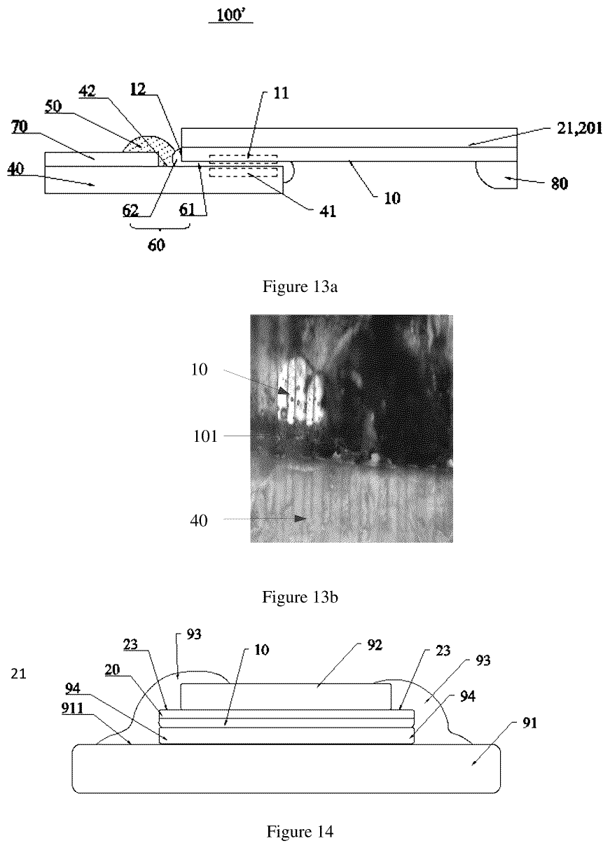

When an acidic or alkaline solution reliability test is carried out on the display module 100 of the embodiments of the present application, sixteen display modules 100 are taken and divided into two groups, with each group containing eight display modules 100. The first group of display modules 100 is subjected to an acidic solution test, and the second group of display modules 100 is subjected to an alkaline solution test. In order to reduce the erosion of the display screen 10 by the acidic or alkaline gas and liquid from the first end 12 of the display screen 10, a common solution is to use a first comparative sample as shown in FIG. 13a. A display module 100′ of the first comparative sample differs from the display module 100 of the embodiments of the present application in that the auxiliary functional layer 21 is flush with the first end 12 of the display screen 10, the display module 100′ of the first comparative sample is provided with no extended bonding surface 31-1 or 31-2 (see FIGS. 2b and 7), the sealant 50 is arranged on the first step surface 42, and the sealant 50 tends to have a gap with the first end 12. In order to reduce the erosion of the display screen 10 by the acidic or alkaline gas and liquid from the first end 12 of the display screen 10, it is also possible to use a second comparative sample as shown in FIG. 1b. A display module 100′ of the second comparative sample differs from the display module 100 of the embodiments of the present application in that the auxiliary functional layer 21 is flush with the first end 12 of the display screen 10, and the display module 100′ of the second comparative sample is provided with no extended bonding surface 31-1 or 31-2 (see FIGS. 2b and 7). The sealant 50 covers the first end 12 of the display screen 10 and an end of the auxiliary functional layer 21, and a part of the sealant 50 is attached in an overlapping manner to the back side of the support film 201. The protective film 22 (see FIG. 1a) and the support film 201 of the display module 100′ of the second comparative sample are flush with the first end 12 of the display screen 10, and after the protective film 22 is removed, one end of a part of the sealant 50 is attached in an overlapping manner to the back side of the support film 201. It has been found through research that after the protective film 22 is removed, there is a gap between the end of the part of the sealant 50 and the support film 201, and it is likely to create a slit between the sealant 50 and the first end 12 of the display screen 10. Specifically, the group of comparative samples in the embodiments of the present application includes the first comparative sample and the second comparative sample. The first comparative sample includes a third group and a fourth group, and the second comparative sample includes a fifth group and a sixth group, with each group containing eight samples. The third and fifth groups were tested with an acidic solution, and the fourth and sixth groups were tested with an alkaline solution.

The specific test method is as follows. As shown in FIGS. 7 and 12-15, the acidic or alkaline solution was dripped to the peripheral side of the edge of the insulating tape 82 outside of the external circuit assembly 40 of the display module 100 of the embodiments of the present application and of the display module 100′ of the group of comparative samples, and to each of four sides of the display module 100. The four sides of the display module 100 include a first side 120, a second side 130, a third side 140 and a fourth side 150. The acidic or alkaline solution was dripped once every 2 hours. Each display module 100 was dripped with the acidic or alkaline solution 12 times, and the reliability of the display module 100 after 24 hours of acidic or alkaline solution test was observed. After the reliability test, the first and second groups of display modules 100 passed the acidic or alkaline solution reliability test, and there was no acidic or alkaline solution sample between the display screen 10 and the first binding area 11 and the second binding area 41. As shown in FIGS. 1c and 13b, there was an acidic or alkaline crystal 101 between the display screen 10 and the first binding area 11 and the second binding area 41 of the comparative sample display modules 100′ (see FIG. 13a) of the third, fourth, fifth and sixth groups, and the comparative samples of the third to sixth groups did not pass the acidic or alkaline solution reliability test.

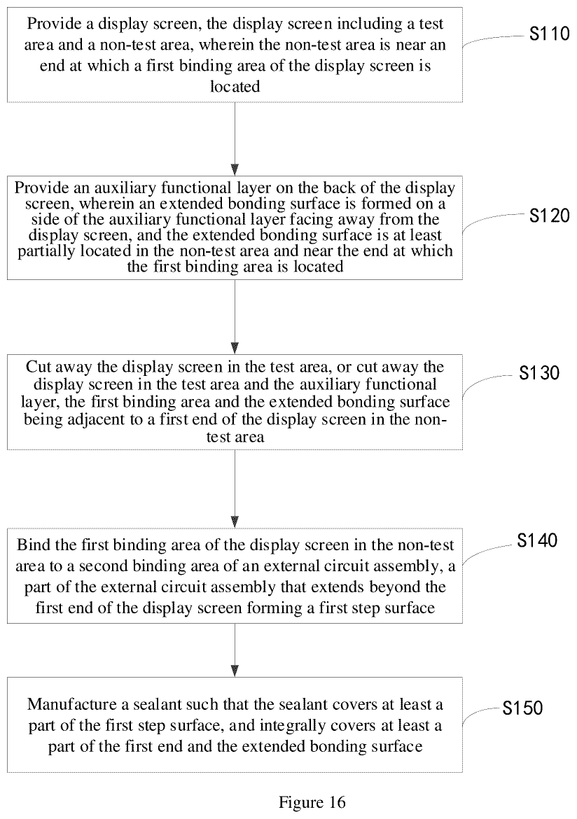

The embodiments of the present application further include a second technical solution. As shown in FIG. 16, a method for manufacturing a display module includes the following steps.

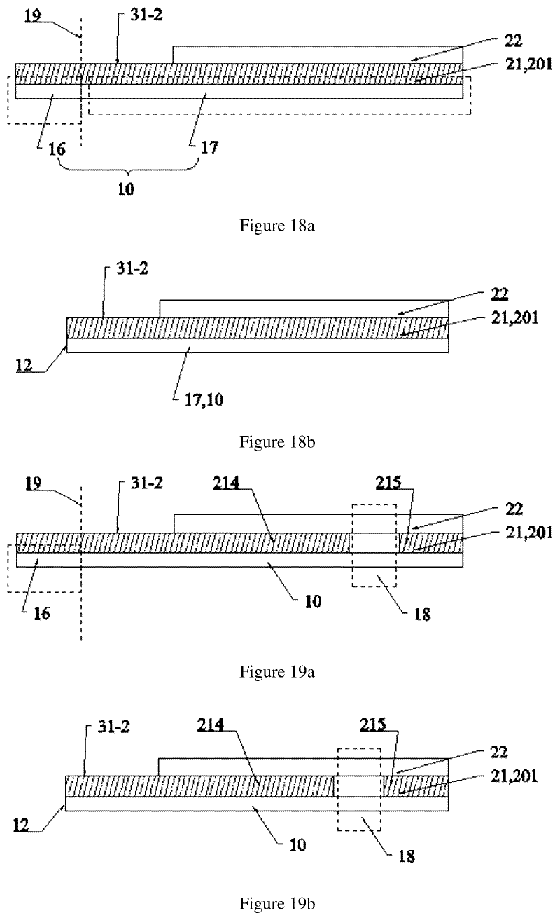

In step S110, as shown in FIG. 18a, a display screen 10 is provided, the display screen 10 including a test area 16 and a non-test area 17. The non-test area 17 is near an end at which a first binding area 11 (see FIG. 2a) of the display screen 10 is located.

In an embodiment of the present application, the test area 16 includes an array substrate, but the test area 16 is provided with no light-emitting device. A partial region of the non-test area 17 on the side close to the test area 16 is provided with no light-emitting device, and a light-emitting device and an encapsulation layer are provided in other regions.

In an embodiment of the present application, the display screen 10 is divided into a test area 16 and a non-test area 17, so that a circuit test can be performed on the test area 16 to test whether there is an abnormality in a circuit of the array substrate of the display screen 10.

In step S120, an auxiliary functional layer 21 is provided on the back side of the display screen 10. An extended bonding surface 31-2 is formed on a side of the auxiliary functional layer 21 facing away from the display screen 10, and the extended bonding surface 31-2 is at least partially located in the non-test area 17 and near the end at which the first binding area 11 is located.

In an embodiment of the present application, the display screen 10 is a flexible display screen. By providing the auxiliary functional layer 21 on the back side of the display screen 10, the auxiliary functional layer 21 can at least support the flexible display screen, to protect the flexible display screen from being wrinkled or damaged. The function of the auxiliary functional layer 21 is not limited in the embodiments of the present application. For example, the auxiliary functional layer 21 may further improve the crease formed by bending the flexible display screen.

In an embodiment of the present application, the auxiliary functional layer 21 includes a support film 201. One end of the support film 201 is flush with the end of the test area 16 away from the non-test area 17, and the support film 201 covers the test area 16 and integrally extends to the non-test area 17. In an embodiment of the present application, the support film 201 integrally covers the back side of the display screen 10. In another embodiment, as shown in FIG. 19a, it is also possible that in a bent area 18 of the display screen 10, the support film 201 is in a disconnected state.

In an embodiment of the present application, a protective film 22 is further provided on a side of the auxiliary functional layer 21 facing away from the display screen 10, and a projection of the protective film 22 on the auxiliary functional layer 21 does not overlap the extended bonding surface 31-2. The protective film 22 is configured to protect the support film 201 to prevent the auxiliary functional layer 21 from being damaged or scratched during transportation. The protective film 22 may also be configured to protect the auxiliary functional layer 21 to prevent foreign matter from being adhered to the auxiliary functional layer 21.

Specifically, in an embodiment of the present application, the protective film 22 is arranged on a side of the support film 201 facing away from the display screen 10. The protective film 22 does not cover the end of the non-test area 17 close to the first binding area 11, so that the support film 201 of the non-test area 17 forms the extended bonding surface 31-2. In an embodiment of the present application, the protective film 22 also does not cover the support film 201 of the test area 16, i.e. the extended bonding surface 31-2 is located between the non-test area 17 and the test area 16. In other embodiments, it is also possible that the protective film 22 is divided into two sections, among which one section of protective film 22 is located in the non-test area 17 and does not cover the end of the non-test area 17 close to the first binding area 11; and the other section of protective film 22 covers the support film 201 of the test area 16.

When the auxiliary functional layer 21 is arranged on the back side of the display screen 10, the test area 16 of the display screen 10 may be tested to detect the presence of an abnormality in the circuit of the display screen 10.

In step S130, as shown in FIGS. 18a, 18b, 19a and 19b, the display screen 10 in the test area 16 is cut away, or the display screen 10 in the test area 16 and the auxiliary functional layer 21 are cut away, and the first binding area 11 (see FIG. 2a) and the extended bonding surface 31-2 are adjacent to a first end 12 of the display screen 10 in the non-test area 17.

In an embodiment of the present application, the test area 16 of the display screen 10 may be cut away after the test area 16 has been tested. Specifically, the display screen 10 in the test area 16 and at least a part of the auxiliary functional layer 21 are cut away. In an embodiment of the present application, cutting is performed along a cutting line 19 to cut away the test area 16. Specifically, in the embodiment of the present application, the cutting line 19 is an edge line of the test area 16 that is close to one side of the non-test area 17. In other embodiments, the cutting line 19 may be located elsewhere between the test area 16 and the non-test area 17.

In an embodiment of the present application, the display screen 10 in the test area 16 is separated from the display screen 10 in the non-test area 17 by performing cutting along the cutting line 19. When the test area 16 is provided with the support film 201, the display screen 10 in the test area 16 and the support film 201 can be cut away simultaneously. When the test area 16 is provided with the support film 201 and the protective film 22, the display screen 10 in the test area 16, the support film 201 and the protective film 22 can be cut away simultaneously.

In an embodiment of the present application, after performing cutting along the cutting line 19, an end of the display screen 10 in the non-test area 17 that is close to the cutting line 19 is the first end 12. The auxiliary functional layer 21 in the non-test area 17 has an extended bonding surface 31-2. The extended bonding surface 31-2 is adjacent to the first end 12 of the display screen 10. The extended bonding surface 31-2 is formed by a region of the non-test area 17 that is adjacent to the support film 201 of the first end 12 and not covered by the protective film 22.

In step S140, as shown in FIG. 2b, the first binding area 11 of the display screen 10 in the non-test area 17 is bound to a second binding area 41 of an external circuit assembly 40, a part of the external circuit assembly 40 that extends beyond the first end 12 of the display screen 10 forming a first step surface 42.

In an embodiment of the present application, the first binding area 11 of the display screen 10 in the non-test area 17 is provided with a first pin, the second binding area 41 of the external circuit assembly 40 is provided with a second pin, and the first pin is electrically connected to the second pin. As shown in FIGS. 4a and 6a, in an embodiment of the present application, a conductive adhesive 60 is further provided between the first binding area 11 and the second binding area 41, so as to further improve the stability of the connection of the first binding area 11 to the second binding area 41.

In step S150, a sealant 50 is manufactured such that the sealant 50 covers at least a part of the first step surface 42, and integrally covers at least a part of the first end 12 and the extended bonding surface 31-2.

In an embodiment of the present application, the sealant 50 is sprayed by using an adhesive valve such that the sealant 50 integrally covers and is bonded to a part of the first step surface 42, a part of the first end 12 and the extended bonding surface 31-2. In other embodiments, the sealant 50 integrally covers and is bonded to the entire first step surface 42, the entire first end 12 or the extended bonding surface 31-2. In an embodiment of the present application, the sealant 50 does not cover the protective film 22, so that when the protective film 22 is removed from the display module 100 later, the protective film 22 will not displace the sealant 50.

In the manufacturing method of an embodiment of the present application, the extended bonding surface 31-2 is formed on the auxiliary functional layer 21 in the non-test area 17, so that the sealant 50 can cover the extended bonding surface 31-2, and also integrally cover the first end 12 of the display screen 10 and the first step surface 42 of the external circuit assembly 40 during the manufacturing such as spraying. In an embodiment of the present application, the sealant 50 can effectively seal the end surface of the first end 12 of the display screen 10. The stability and reliability of the display module 100 are improved, and the service life of the display module 100 is prolonged, without increasing the number of manufacturing processes.

In a particular embodiment of the present application, a nozzle is positioned above the display module 100 such that an orthographic projection of the nozzle on the display module 100 is located on the first step surface 42, and a sealant 50 is sprayed such that the sealant 50 flows from the first step surface 42 to the first end 12 and the extended bonding surface 31-2. In an embodiment of the present application, the sealant 50 is sprayed by using a spraying device, and the nozzle of the spraying device is positioned above the first step surface 42 so that the sealant 50 can first come into contact with the first step surface 42. As the spraying device continues to spray the sealant 50, the sealant 50 propagates from first step surface 42 to the first end 12 and further to the extended bonding surface 31-2. In an embodiment of the present application, during the manufacturing of the sealant 50, since the first step surface 42 is at the same height as one end of the first end 12 and the other regions of the first end 12 are higher than the first step surface 42, as the sealant 50 propagates from the first step surface 42 of a relatively low height to the first end 12, the fluidity of the sealant enables the sealant 50 to propagate to the first end 12 such that the sealant 50 is adhered to the first step surface 42 and at the same time, the sealant 50 can be adhered to the junction between the first step surface 42 and the first end 12, and cover and be bonded to the first end 12, so that the sealant 50 is adhered to the first end 12 and the first step surface 42, with no gap between the sealant 50 and each of the first end 12 and the first step surface 42. In particular, there is no gap between the sealant 50 and the contact between the first end 12 and the first step surface 42.

In an embodiment of the present application, during the propagation of the sealant 50 from the first end 12 to the extended bonding surface 31-2, since the highest end of the first end 12 is at the same height as the extended bonding surface 31-2 and the other regions of the first end 12 are lower than the extended bonding surface 31-2, as the sealant 50 propagates from the first end 12 of a relatively low height to the extended bonding surface 31-2, the fluidity of the sealant enables the sealant 50 to propagate to the extended bonding surface 31-2 such that the sealant 50 can be adhered to the junction between the first end 12 and the extended bonding surface 31-2, and cover and be bonded to the extended bonding surface 31-2, so that the sealant 50 is adhered to the first end 12 and the first step surface 42, with no gap between the sealant 50 and each of the first end 12 and the extended bonding surface 31-2. The sealant 50 is manufactured by positioning the nozzle of the spraying device above the first step surface 42, so that the sealant 50 can better integrally cover and be bonded to at least a part of the first step surface 42, at least a part of the first end 12 and the extended bonding surface 31-2, and there will be no gap or void caused by the manufacturing process between the sealant 50 and each of the first step surface 42, the first end 12 and the extended bonding surface 31-2. In this way, it is possible to improve the sealing effect of the sealant 50 sealing the first end 12, to improve the stability and reliability of the display module 100, and to prolong the service life of the display module 100.

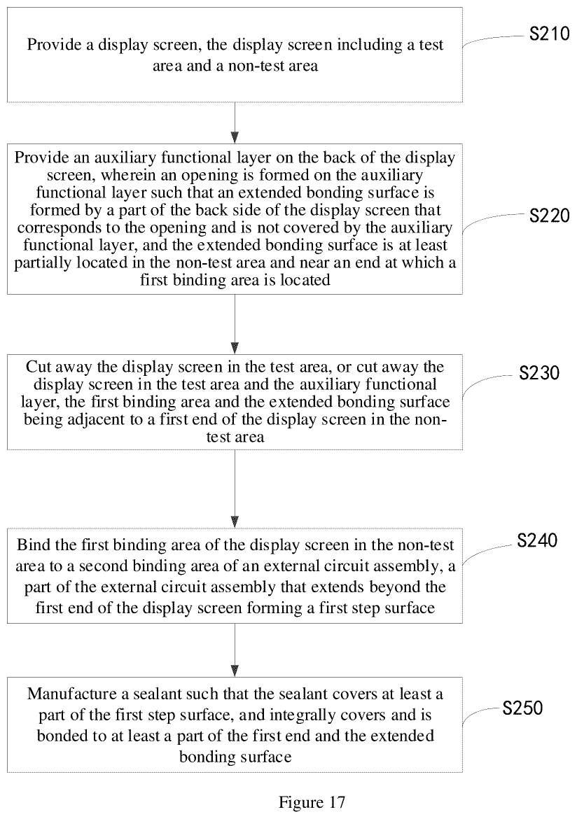

In another embodiment of the present application, as shown in FIG. 17, a method for manufacturing a display module 100 includes the following steps.

In step S210, as shown in FIG. 20a, a display screen 10 is provided, the display screen 10 including a test area 16 and a non-test area 17.

The step is the same as that of step S110 in the above embodiment and will not be described here.

In step S220, an auxiliary functional layer 21 is provided on the back side of the display screen 10. An opening 24 is formed on the auxiliary functional layer 21 such that an extended bonding surface 31-1 is formed by a part of the back side of the display screen 10 that corresponds to the opening and is not covered by the auxiliary functional layer 21, and the extended bonding surface 31-1 is at least partially located in the non-test area 17 and near the end at which the first binding area 11 is located.

In an embodiment of the present application, the display screen 10 is a flexible display screen. By providing the auxiliary functional layer 21 on the back side of the display screen 10, the auxiliary functional layer 21 can at least support the flexible display screen, to protect the flexible display screen from being wrinkled or damaged.

In an embodiment of the present application, the auxiliary functional layer 21 includes a first auxiliary portion and a second auxiliary portion. The first auxiliary portion covers at least the display screen 10 in the test area 16, the second auxiliary portion is superposed on the display screen 10 in the non-test area 17, there is a spacing between the first auxiliary portion and the second auxiliary portion, and the extended bonding surface 31-1 is formed by a part of the back side of the display screen 10 at the spacing.

In a particular embodiment of the present application, the first auxiliary portion just covers the display screen 10 in the test area 16. The second auxiliary portion does not completely cover the display screen 10 in the non-test area 17, so that the extended bonding surface 31-1 is formed by the back, which is not covered by the auxiliary functional layer 21, of the display screen 10 in the non-test area 17.

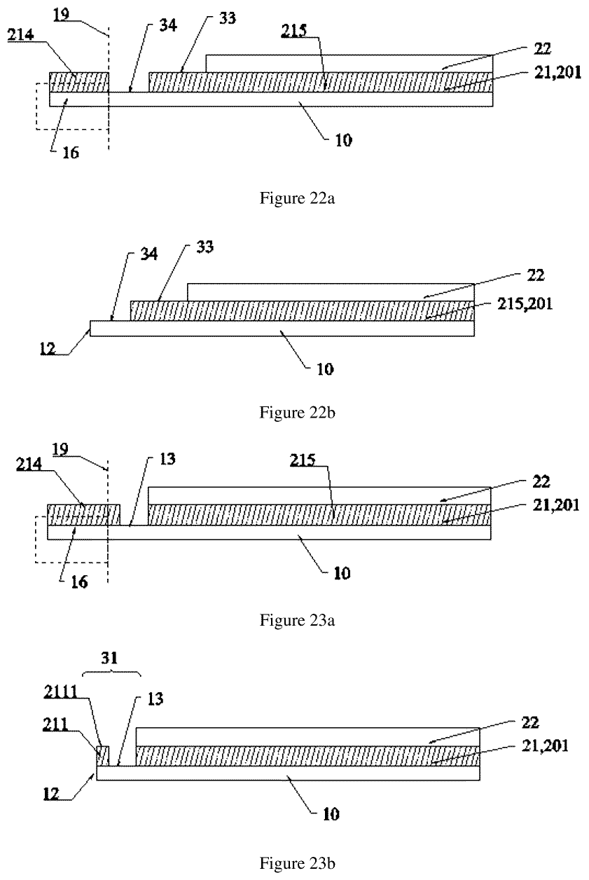

In an embodiment of the present application, the auxiliary functional layer 21 includes a support film 201, and the display module 100 further includes a protective film 22. The protective film 22 is located on the side of the auxiliary functional layer 21 facing away from the display screen 10. In an embodiment of the present application, the support film 201 is divided into three sections, among which a first section of support film 214 is located in the test area 16, a second section of support film 215 and a third section of support film 216 are both located in the non-test area 17, and there is a spacing between the second section of support film 215 and the first section of support film 214. This spacing makes the part of the back side of the display screen 10 that is not covered by the support film 201 form the extended bonding surface 31-1. There is a spacing between the third section of support film 216 and the second section of support film 215. This spacing is located in the bent area 18 of the display screen 10. In an embodiment of the present application, the protective film 22 integrally covers and is bonded to the second section of support film 215 and the third section of support film 216. In an embodiment of the present application, the protective film 22 is flush with an end surface of the second section of support film 201. As shown in FIG. 22a, in other embodiments, it is also possible that the protective film 22 does not completely cover the second section of support film 201 such that the region of the second section of support film 201 not covered by the protective film 22 forms a third step surface 23. As shown in FIG. 20a, in an embodiment of the present application, the first section of support film 214 constitutes a first auxiliary portion; and the second section of support film 215, the third section of support film 216 and the protective film 22 constitute a second auxiliary portion.

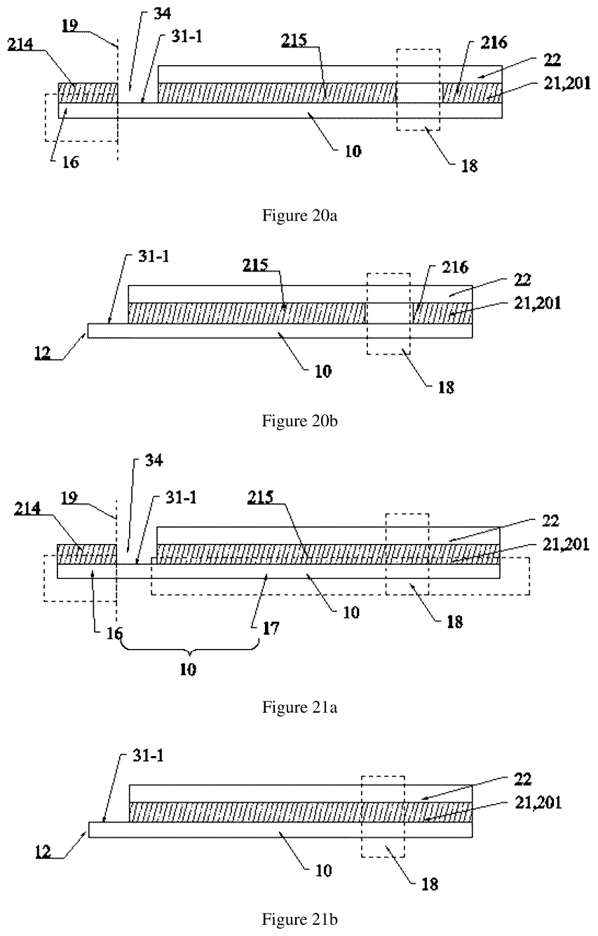

In other embodiments, as shown in FIG. 21a, it is also possible that the support film 201 is divided into two segments, among which a first section of support film 214 is located in the test area 16, a second section of support film 215 is located in the non-test area 17, and there is a spacing between the second section of support film 215 and the first section of support film 214. This spacing makes the part of the back side of the display screen 10 that is not covered by the support film 201 form the extended bonding surface 31-1. In an embodiment of the present application, the first section of support film 201 constitutes a first auxiliary portion; and the second section of support film 215 and the protective film 22 constitute a second auxiliary portion.

In another embodiment, as shown in FIG. 23a, the first section of support film 201 covers the display screen 10 in the test area 16 and integrally extends to cover the display screen 10 in a part of the non-test area 17.

In step S230, as shown in FIGS. 20a and 20b, the display screen 10 in the test area 16 is cut away, or the display screen 10 in the test area 16 and the auxiliary functional layer 21 are cut away, and the first binding area 11 (see FIG. 2a) and the extended bonding surface 31-1 are adjacent to a first end 12 of the display screen 10 in the non-test area 17.

In an embodiment of the present application, the cutting line 19 is an edge line of the test area 16 that is close to the non-test area 17. In other embodiments, the cutting line 19 may be located at a different position.

In an embodiment of the present application, by performing cutting along the cutting line 19, the display screen 10 in the test area 16 and at least a part of the first auxiliary portion in the test area 16 are cut away. The extended bonding surface 31-1 is formed by a part, which is not covered by the auxiliary functional layer 21, of the back side of the display screen 10 in the non-test area 17.

In another embodiment, as shown in FIGS. 22a and 22b, a first extended bonding surface 33 is formed by a region of the second section of support film 215 that is not covered by the protective film 22, and a second extended bonding surface 34 is formed by a part, which is not covered by the support film 201, of the back side of the display screen 10 in the non-test area 17.

In still another embodiment, as shown in FIGS. 23a and 23b, when the first section of support film 214 covers the display screen 10 in the test area 16 and integrally extends to cover the display screen 10 in a part of the non-test area 17, by performing cutting along the cutting line 19, the first section of support film 214 is cut apart such that a first support portion 211 is formed by the first section of support film 201 located in the non-test area 17.

In step S240, as shown in FIG. 3, the first binding area 11 of the display screen 10 in the non-test area 17 is bound to a second binding area 41 of an external circuit assembly 40, a part of the external circuit assembly 40 that extends beyond the first end 12 of the display screen 10 forming a first step surface 42.

The step is the same as that of step S140 in the above embodiment and will not be described here.

In step S250, as shown in FIG. 3, a sealant 50 is manufactured such that the sealant 50 covers at least a part of the first step surface 42, and integrally covers and is bonded to at least a part of the first end 12 and the extended bonding surface 31-1.

In an embodiment of the present application, the sealant 50 is sprayed by using an adhesive valve such that the sealant 50 integrally covers a part of the first step surface 42, a part of the first end 12 and the extended bonding surface 31-1. In another embodiment, the sealant 50 integrally covers the entire first step surface 42, the entire first end 12 and the extended bonding surface 31-1. In an embodiment of the present application, the sealant 50 does not cover the protective film 22, so that when the protective film 22 is removed from the display module 100 later, the protective film 22 will not displace the sealant 50. In still another embodiment, as shown in FIG. 9, it is also possible that the sealant 50 integrally covers and is bonded to at least a part of the first step surface 42, at least a part of the first end 12, at least a part of each of two ends of the first support portion 211, at least a part of a surface 2111 of the first support portion 211 facing away from the display screen 10 and at least a part of the back side of the display screen 10 at the spacing. The extended bonding surface 31 includes the surface 2111 of the first support portion 211 facing away from the display screen 10 and the back side of the display screen 10 at the spacing. As shown in FIG. 8a, in yet another embodiment, the sealant 50 integrally covers at least a part of the first step surface 42, at least a part of the first end 12, at least a part of the extended bonding surface 31-1 and at least a part of the third step surface 32.

In the manufacturing method of an embodiment of the present application, the extended bonding surface 31-1 is formed by a part of the back side of the display screen 10 that is not covered by the auxiliary functional layer 21, so that the sealant 50 can cover and be bonded to the extended bonding surface 31-1, and also integrally cover and be bonded to the first end 12 of the display screen 10 and the first step surface 42 of the external circuit assembly 40 during the manufacturing such as spraying. In an embodiment of the present application, the sealant 50 can effectively seal the end surface of the first end 12 of the display screen 10. The stability and reliability of the display module 100 are improved, and the service life of the display module 100 is prolonged, without increasing the number of manufacturing processes.

An embodiment of the present application further includes a third technical solution, i.e., a display device, including a drive circuit and the display module 100 described above, the drive circuit being configured to drive the display module 100. In the display device of the embodiment of the present application, by forming an extended bonding surface 31-2 on the side of the auxiliary functional layer 21 facing away from the display screen 10 or an extended bonding surface 31-2 on the back side of the display screen 10 that is not covered by the auxiliary functional layer 21, and by making the sealant 50 cover at least a partial region of the first step surface 42, the sealant 50 further extends to cover at least a partial region of the first end 12 and the extended bonding surface 31 or 31-2, so that the sealant 50 of the display module 100 of the embodiment of the present application can effectively seal an end surface of the first end 12 of the display screen 10, and integrally seal an end of a gap between the external circuit assembly 40 and the display screen 10. The acidic or alkaline high-humidity gas or liquid can be prevented from entering the interior of the display screen 10 from the first end 12 of the display screen 10, corroding a circuit in the display screen 10, and affecting the display of the display screen 10 and thus the display of the display device. The embodiment of the present application can improve the stability and reliability of the display device and prolong the service life of the display device.

The above are merely the embodiments of the present application and are not intended to limit the patent scope of the present application, and any equivalent structure or equivalent process alternation made by using the content of the specification and drawings of the present application, or an application of the content of the specification and drawings directly or indirectly to another related technical field, shall fall within the scope of protection of the present application.

What is claimed is:

1. A display module, comprising:
a display screen, comprising a first binding area arranged on a side, where a light exit surface of the display screen is located, of the display screen, and the first binding area being adjacent to a first end of the display screen;
an auxiliary functional layer, arranged on a back side of the display screen and comprising an extended bonding surface formed on a side of the auxiliary functional layer facing away from the display screen, or the display screen comprising an extended bonding surface formed by a part of the back side of the display screen that is not covered by the auxiliary functional layer;
an external circuit assembly, provided with a second binding area, and bound and connected to the first binding area of the display screen by means of the second binding area, a part of the external circuit assembly that extends beyond the first end of the display screen forming a first step surface; and
a sealant, the sealant covering at least a part of the first step surface, at least a part of the first end, and the extended bonding surface.

2. The display module according to claim 1, wherein the extended bonding surface is formed by the part of the back side of the display screen that is not covered by the auxiliary functional layer, the extended bonding surface has a dimension greater than a manufacturing accuracy of the sealant in a direction from the first step surface to the second binding area, and the sealant does not cover a surface of the auxiliary functional layer facing away from the display screen.

3. The display module according to claim 1, wherein an end of the auxiliary functional layer is flush with the first end of the display screen, the extended bonding surface is formed on the side of the auxiliary functional layer facing away from the display screen, and the extended bonding surface has a dimension greater than a manufacturing accuracy of the sealant in a direction from the first step surface to the second binding area.

4. The display module according to claim 1, wherein the auxiliary functional layer and the display screen comprise the extended bonding surface respectively, the auxiliary functional layer comprises a support film, the extended bonding surface of the auxiliary functional layer comprises a first extended bonding surface formed on a side of the support film facing away from the display screen, and the extended bonding surface of the display screen comprises a second extended bonding surface; and
the sealant covers the first extended bonding surface and the second extended bonding surface.

5. The display module according to claim 4, wherein a sum of the dimension of the first extended bonding surface and the dimension of the second extended bonding surface is greater than a manufacturing accuracy of the sealant in a direction from the first step surface to the second binding area.

6. The display module according to claim 1, wherein the auxiliary functional layer comprises a support film located on the back side of the display screen, the support film comprises:
a first support portion adjacent to the first end; and
a second support portion having a spacing from the first support portion, the second support portion being located on a side of the first support portion away from the first end;
the extended bonding surface comprises at least a partial region of a surface of the first support portion facing away from the display screen and at least a partial region of the back side of the display screen at the spacing; and
the sealant covers at least a part of each of two end surfaces of the first support portion, and the two end surfaces of the first support portion are respectively adjacent to the back side of the first support portion.

7. The display module according to claim 6, wherein the display module comprises a third extended bonding surface formed on a side of the second support portion facing away from the display screen, and the sealant further integrally covers and is bonded to the third extended bonding surface.

8. The display module according to claim 7, wherein a sum of a dimension of the extended bonding surface and a dimension of the third extended bonding surface is greater than the manufacturing accuracy of the sealant in a direction from the first step surface to the second binding area.

9. The display module according to claim 1, further comprising:
a conductive adhesive, wherein the conductive adhesive is located between the first binding area and the second binding area, or a part of the conductive adhesive is located between the first binding area and the second binding area, another part of the conductive adhesive is exposed to the first end, and the sealant covers and is bonded to the another part of the conductive adhesive.

10. The display module according to claim 1, further comprising:
a protective film located on the side of the auxiliary functional layer facing away from the display screen.

11. The display module according to claim 10, wherein the extended bonding surface is formed on the side of the auxiliary functional layer facing away from the display screen, a projection of the protective film on the auxiliary functional layer does not overlap the extended bonding surface.

12. The display module according to claim 1, further comprising a covering layer arranged on a surface of the external circuit assembly facing the auxiliary functional layer for protecting the external circuit assembly, wherein an end of the first step surface adjacent to the first end is exposed to the covering layer.

13. The display module according to claim 1, further comprising:
a cover plate disposed at the light exit surface of the display screen, the cover plate comprising at least one second step surface formed by a part of a surface of the cover plate that is not covered by the display screen and faces the display screen;
a protective layer arranged on a surface of the auxiliary functional layer facing away from the display screen, and the auxiliary functional layer comprising at least one third step surface formed by a part of a surface of the auxiliary functional layer that is not covered by the protective layer and faces the protective layer; and
a reinforcing adhesive, which integrally covers at least a part of the second step surface, at least a part of a side surface of each of the display screen and the auxiliary functional layer, and at least a part of the third step surface.

14. The display module according to claim 13, wherein the display module comprises a first side, a second side, a third side and a fourth side, wherein the first side is the side on which the first binding area is located; the second side and the third side are both adjacent to the first side, and the fourth side is opposite to the first side; and the second step surface and the third step surface are provided on each of the second side and the third side, and the reinforcing adhesive is provided on the second side and the third side.

15. A method for manufacturing a display module, the method comprising:
providing a display screen, the display screen comprising a test area and a non-test area, wherein the non-test area is near an end at which a first binding area of the display screen is located;
providing an auxiliary functional layer on the back side of the display screen, wherein an extended bonding surface is formed on a side of the auxiliary functional layer facing away from the display screen, or is formed by a part of the back side of the display screen which is not covered by the auxiliary functional layer, wherein the extended bonding surface is at least partially located in the non-test area and near the end at which the first binding area is located;
cutting away the display screen in the test area, or cutting away the display screen in the test area and the auxiliary functional layer, the first binding area and the extended bonding surface being adjacent to a first end of the display screen in the non-test area;
binding the first binding area of the display screen in the non-test area to a second binding area of an external circuit assembly, a part of the external circuit assembly that extends beyond the first end of the display screen forming a first step surface; and
manufacturing a sealant, wherein the sealant covers at least a part of the first step surface, and integrally covers and is bonded to at least a part of the first end and the extended bonding surface.

16. The method for manufacturing a display module according to claim 15, wherein
the auxiliary functional layer comprises a first auxiliary portion and a second auxiliary portion,
providing the auxiliary functional layer on the back side of the display screen comprises:
manufacturing the first auxiliary portion and the second auxiliary portion separately on the back side of the display screen, the first auxiliary portion covering at least the display screen in the test area, the second auxiliary portion being superposed on the display screen in the non-test area, wherein a spacing is defined between the first auxiliary portion and the second auxiliary portion, and the extended bonding surface is formed on the back side of the display screen at the spacing; and
cutting away the display screen in the test area and the auxiliary functional layer comprises:
cutting away the display screen in the test area and at least a part of the first auxiliary portion in the test area.

17. The method for manufacturing a display module according to claim 16, wherein the first auxiliary portion comprises a first section of support film, the first section of support film covering the display screen in a part or the entirety of the non-test area, or the first section of support film covering the display screen in the non-test area and integrally extending to cover the display screen in a part of the test area; and
cutting away the display screen in the test area and at least a part of the first auxiliary portion in the test area comprises:
cutting away the display screen in the test area and at least a part of the first auxiliary portion in the test area along a cutting line, the cutting line being an edge line of the test area close to the non-test area.

18. The method for manufacturing a display module according to claim 15, wherein
manufacturing the sealant comprises:
positioning a nozzle above the display module, and an orthographic projection of the nozzle on the display module is located on the first step surface; and
spraying a sealant, and the sealant flows from the first step surface to the first end and the extended bonding surface.

19. The method for manufacturing a display module according to claim 15, wherein binding the first binding area of the display screen in the non-test area to a second binding area of an external circuit assembly comprises:
providing a conductive adhesive, a part of the conductive adhesive being located between the first binding area and the second binding area and the other part of the conductive adhesive being exposed to the first end; and
manufacturing the sealant comprises:
manufacturing a sealant, and the sealant covers at least a part of the first step surface, and integrally covers and is bonded to the other part of the conductive adhesive and the extended bonding surface.

20. A display device, comprising a drive circuit and a display module according to claim 1, the drive circuit being configured to drive the display module.
